(19) United States
(12) Patent Application Publication
(10) Pub. No.: US 2008/0265957 A1
(43) Pub. Date: Oct. 30, 2008

(54) Self-Resetting Phase Frequency Detector with Multiple Ranges of Clock Difference

(76) Inventors: Trong V. Luong, Austin, TX (US); Hung C. Ngo, Austin, TX (US); Jethro C. Law, Austin, TX (US); Peter J. Klim, Austin, TX (US)

Correspondence Address: HAMILTON & TERRILE, LLP;IBM Austin, P.O. BOX 203518, AUSTIN, TX, 78720, US

(21) Appl. No.: 11/739,760

(22) Filed: Apr. 25, 2007

(51) Int. Cl. H03L 7/06

(52) U.S. Cl. 327/156

(57) ABSTRACT

A phase detector which provides a dynamic output signal and which automatically resets if a reference clock signal and a feedback clock signal align after an output pulse is generated. With the phase detector in accordance with the present invention, when there is a difference between the positive clock edges of the reference clock signal and the feedback clock signal, the phase detector generates output pulse. The output is used to correct the feedback clock signal. In the next cycle, if the feedback signal is corrected so that both the reference clock signal and feedback clock signal are aligned, then the output signals are reset to zero. The ability to reset advantageously prevents an unexpected correction that can occur in certain phase detector designs.

### BACKGROUND OF THE INVENTION

1. Field of the Invention

The present invention relates to phase frequency detectors, and more particularly, to self-resetting phase frequency detectors.

2. Description of the Related Art

It is known to include a phase detector as a fundamental functional block of a phase locked loop (PLL) or a delay locked loop (DLL). It is known to provide analog phase detectors that interface with a charge pump. It is also known to provide digital phase detectors that generate static up/down signals. Certain digital phase detectors can generate up/down pulses. The phase detector compares the edges (either rising or falling) between a reference clock signal and a feedback clock signal. When the phase detector detects a difference between these two clock edges, the phase detector generates an output pulse. This output pulse is then used to correct the feedback clock signal. When the feedback clock signal is corrected, and thus there is no difference detected between edges of the reference clock signal and the feedback clock signal, the output pulse should be reset. If this output pulse is not reset, then the feedback clock signal may be corrected again unexpectedly.

Many phase detectors produce an output pulse proportional to an actual phase angle shift between the two signals. In digital phase detectors, the input signals are binary and the phase error can only be determined each clock cycle. If the phase error is leading, then the voltage controlling the delay line should slew in one direction (e.g., increase) and if the phase error is lagging, then the voltage should slew in the other direction (e.g., decrease).

Many phase detectors have been designed in conjunction with a cross nand latch. For example, FIG. 1, labeled prior art, shows an example of a phase detector which includes a cross NAND latch. Such a cross nand latch provides a static output which would be unable to control a dynamic circuit such as a dynamic counter circuit.

It is desirable to provide a phase detector which provides a dynamic output signal and which automatically resets if a reference clock signal and a feedback clock signal align after an output pulse is generated.

### SUMMARY

In accordance with the present invention, a phase detector which provides a dynamic output signal and which automatically resets if a reference clock signal and a feedback clock signal align after an output pulse is generated is set forth. With the phase detector in accordance with the present invention, when there is a difference between the positive clock edges of the reference clock signal and the feedback clock signal, the phase detector generates output pulse. The output is used to correct the feedback clock signal. In the next cycle, if the feedback signal is corrected so that both the reference clock signal and feedback clock signal are aligned, then the output signals are reset to zero. The ability to reset advantageously prevents an unexpected correction that can occur in certain phase detector designs.

Additionally, the phase detector in accordance with the present invention detects the magnitude of the difference between two clocks and then generates multiple pulses. Thus, the phase detector not only compares between the two clock edges but also monitors the feedback clock signal. When a small difference between the two clock edges is detected, this phase detector creates either up or down pulse (which can for example, inform a counter to fix the feedback clock signal). When a large difference is detected, the phase detector generates a second up or down pulse. This second up or down pulse can be used to indicate that the difference between a reference signal and a feedback signal is getting worse. In certain embodiments, the phase detector can be modified to generate additional pulses when the magnitude of the difference between the reference signal and the feedback signal continues to increase.

A phase detector in accordance with the present invention can be used as an application of Skitter circuits which are used to measure timing uncertainty at different locations within an integrated circuit. Additionally, a phase detector in accordance with the present invention can be used to compare data at different locations on an integrated circuit against reference data. If a difference is detected, then the phase detector generates pulses. The larger the magnitude of the difference between the data needs to be monitored and the reference data, the larger the number of pulses that can be generated at the output of the phase detector.

### BRIEF DESCRIPTION OF THE DRAWINGS

Selected embodiments of the present invention may be understood, and its numerous objects, features and advantages obtained, when the following detailed description is considered in conjunction with the following drawings, in which:

FIG. 1, labeled prior art, shows a block diagram of an exemplative phase detector which includes a cross nand latch.

FIG. 2 shows a schematic block diagram of a phase detector in accordance with the present invention.

FIG. 3 shows a schematic block diagram of a stretching circuit.

FIG. 4 shows a timing diagram of the operation of a stretching circuit.

FIG. 5 shows a timing diagram of the operation of the phase detector.

FIG. 6 shows a timing diagram of the operation of the phase detector when the reference signal and the feedback signal are aligned.

FIG. 7 shows a timing diagram of the generation of a second down pulse.

FIG. 8 shows a timing diagram of the operation of the phase detector when a positive edge of the feedback signal leads the positive edge of the reference clock signal.

FIG. 9 shows a schematic block diagram of an embodiment of the phase detector in which multiple ranges of differences may be detected.

FIG. 10 shows a block diagram of a data processing system suitable for practicing embodiments of the present invention.

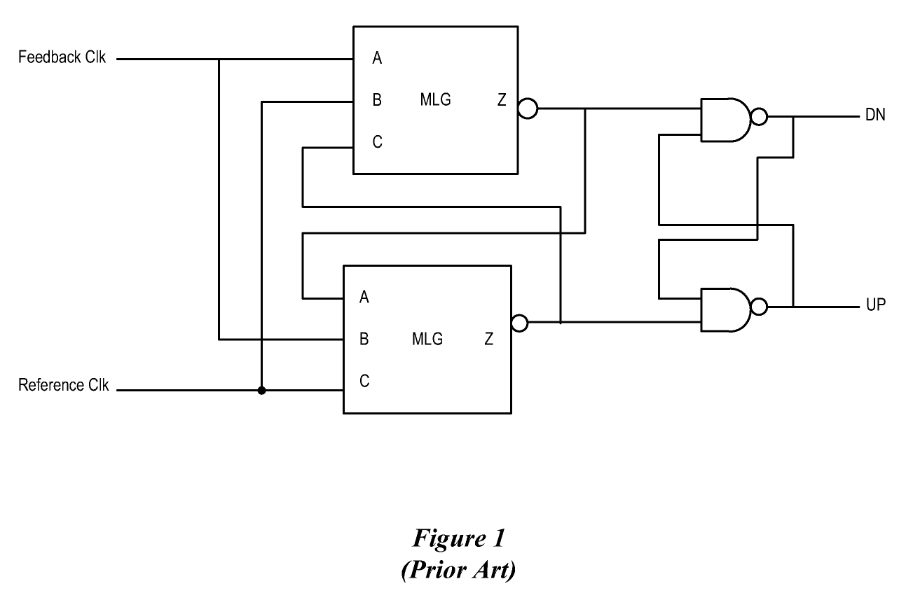

### DETAILED DESCRIPTION

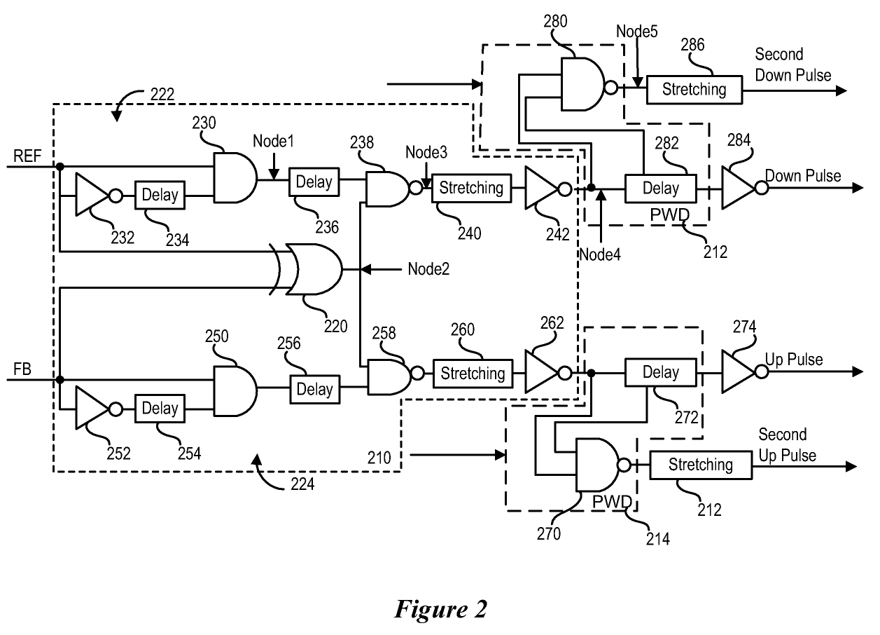

Referring to FIG. 2, a schematic block diagram is provided of a phase detector 200 in accordance with the present invention. More specifically, the phase detector 200 includes a mismatch pulse generator circuit 210 as well as an up pulse width detector circuit 212 and a down pulse width detector circuit 214. The mismatch pulse generator circuit 210 includes an exclusive OR gate 220 as well as a trailing edge detection circuit 222 and a leading edge detection circuit 224. The exclusive OR gate 220 receives as inputs the reference clock signal (REF) and the feedback clock signal (FB).

The trailing edge circuit 222 includes an AND gate 230, an inverter 232, a delay circuit 234 and a delay circuit 236. The reference signal circuit 222 also includes a NAND gate 238, a stretching circuit 240 and an inverter 242.

The reference signal is provided to an input of the AND gate 230 as well as an input of the inverter 232. The output of the inverter 232 is provided to an input of the delay circuit 234. The output of the delay circuit 234 is provided as an input to the AND gate 230. The output of the AND gate 230 is provided to the delay circuit 236. The output of the delay circuit 236 is provided as an input to the NAND gate 238. The NAND gate 238 also receives the output of the exclusive OR gate 220 as an input.

The output of the NAND gate 238 is provided to the stretching circuit 240. The output of the stretching circuit 240 is provided to the inverter 242. The output of the inverter 242 is provided to the down pulse width detector circuit 214.

The leading edge detection circuit 224 includes an AND gate 250, an inverter 252, a delay circuit 254 and a delay circuit 256. The leading edge detection circuit 224 also includes a NAND gate 258, a stretching circuit 260 and an inverter 262.

The reference signal is provided to an input of the AND gate 250 as well as an input of the inverter 252. The output of the inverter 252 is provided to an input of the delay circuit 252. The output of the delay circuit 252 is provided as an input to the AND gate 250. The output of the AND gate 250 is provided to the delay circuit 256. The output of the delay circuit 256 is provided as an input to the NAND gate 258. The NAND gate 258 also receives the output of the exclusive OR gate 220 as an input.

The output of the NAND gate 258 is provided to the stretching circuit 260. The output of the stretching circuit 260 is provided to the inverter 262. The output of the inverter 262 is provided to the up pulse width detector circuit 212.

The up pulse detector circuit 212 includes a NAND gate 270 and a delay circuit 272. The output of the inverter 262 is provided to the NAND gate 270 and to the delay circuit 272. An output of the delay circuit 272 is also provided as an input to the NAND gate 270. The output of the delay circuit 272 is provided an inverter 274. The output of the inverter 274 is provided as an up pulse signal. The output of the NAND gate 270 is provided to a stretching circuit 276. The output of the stretching circuit 276 is provided as a second up pulse signal.

The down pulse detector circuit 214 includes a NAND gate 280 and a delay circuit 282. The output of the inverter 242 is provided to the NAND gate 280 and to the delay circuit 282. An output of the delay circuit 282 is also provided as an input to the NAND gate 280. The output of the delay circuit 282 is provided an inverter 284. The output of the inverter 284 is provided as a down pulse signal. The output of the NAND gate 280 is provided to a stretching circuit 286. The output of the stretching circuit 286 is provided as a second down pulse signal.

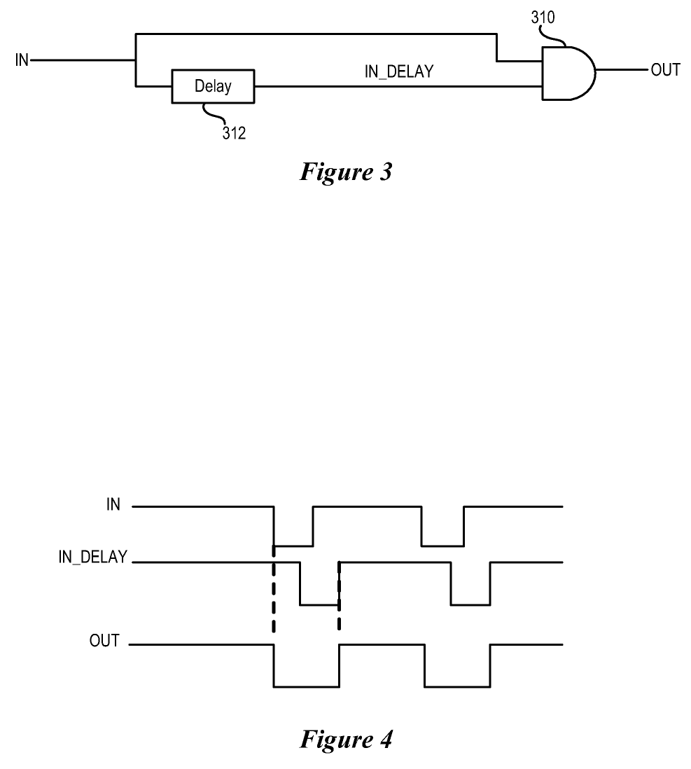

FIG. 3 shows a schematic block diagram of a stretching circuit 300. More specifically, the stretching circuit includes a AND gate 310 and a delay circuit 312. An input signal (e.g., IN) is received as an input by both the AND gate 310 and the delay circuit 312. The output of the delay circuit is also provided as an input to the AND gate 310. The output of the AND gate 310 provides the output signal (OUT) of the stretching circuit.

FIG. 4 shows a timing diagram of the operation of a stretching circuit 300. The stretching circuit receives an input signal and stretches the pulse width of the input signal to provide an output signal with a wider pulse width. The input pulse is delayed by an amount that does not exceed with width of the input pulse (see e.g., the IN₁₃ DELAY) signal. Thus when the In signal and the IN_DELAY signal are nanded, the result is a signal having a pulse that is wider than the pulse of the input signal (IN).

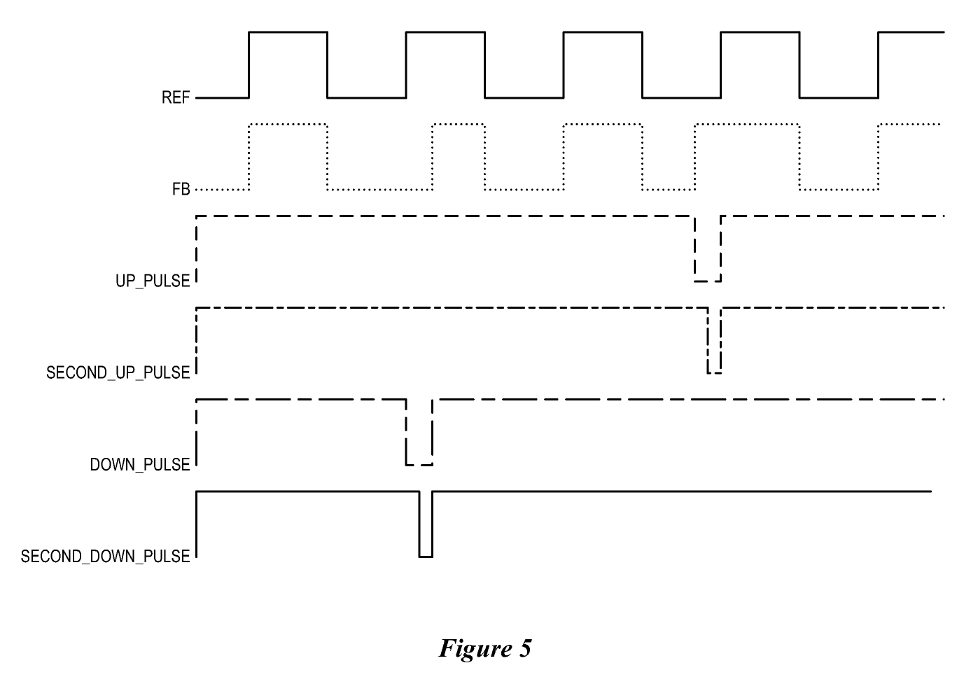

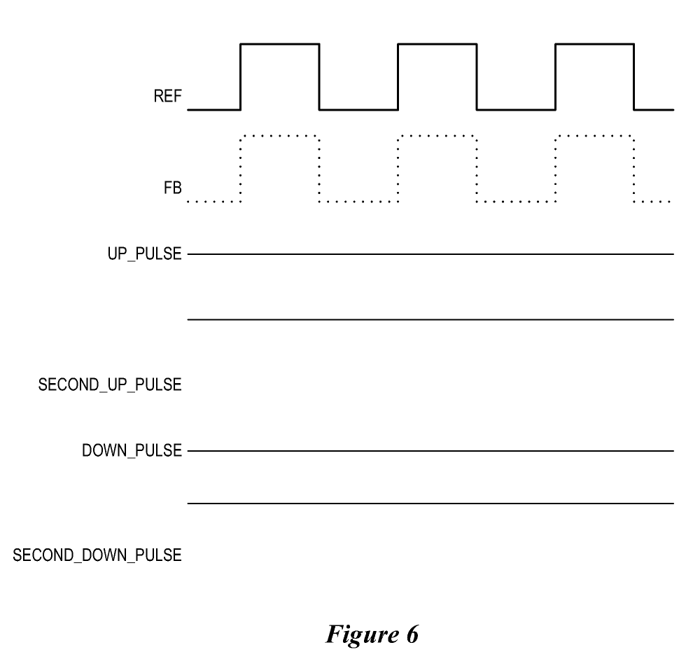

Referring to FIGS. 5 and 6, timing diagrams of the operation of the phase detector 200 are shown. FIG. 5 shows a timing diagram of the operation of the phase detector when the reference signal and the feedback signal are not aligned. FIG. 6 shows a timing diagram of the operation of the phase detector when the reference signal and the feedback signal are aligned.

More specifically, referring to FIG. 5, when there is a mismatch between positive edges of the reference signal and the feedback signal, the phase detector 200 generates either down pulses or up pulses depending on whether edge of the feedback signal is behind (i.e., trailing) or ahead (i.e., leading) of the edge of the reference signal. When the positive edge of feedback signal is trailing the positive edge of reference signal, the phase detector 200 generates a down pulse. When the positive edge of the feedback signal is leading the positive edge of the reference signal, the phase detector 200 generates an up pulse. Depending on the magnitude of the difference between the two positive edges, a second pulse up or down pulse may or may not be generated.

Referring to FIG. 6, when the positive edges of the reference signal and feedback signal are aligned (i.e., the reference signal and the feedback signal edges are synchronized), the phase detector 200 does not generate either up pulses or down pulses. More specifically, the UP PULSE signal, the SECOND UP PULSE signal, the DOWN PULSE signal and the SECOND DOWN PULSE signal all remain in their inactive state (e.g., their high state).

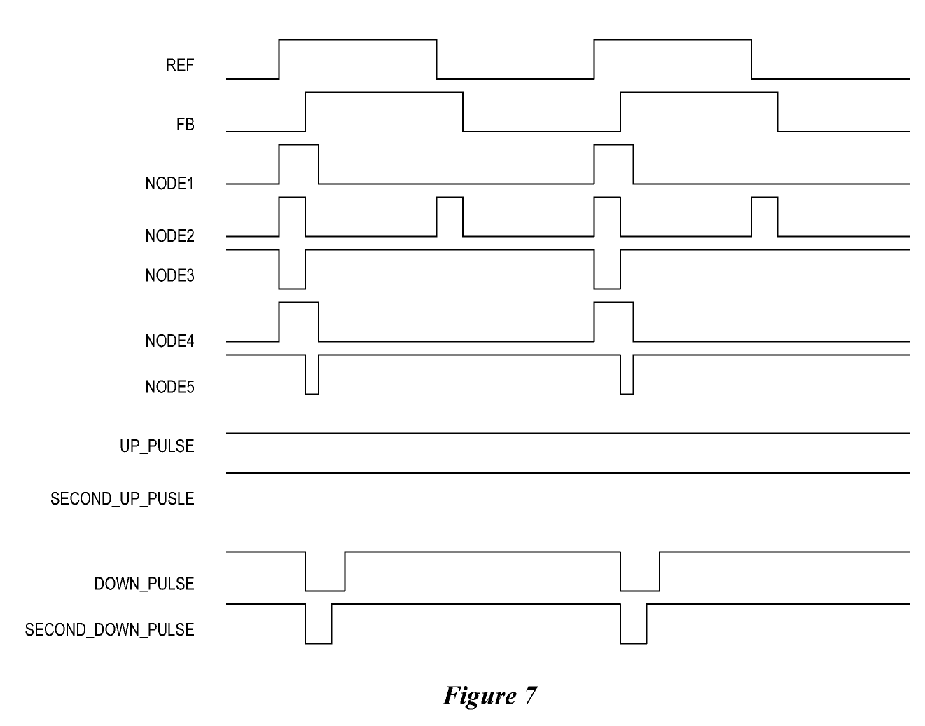

FIG. 7 shows a more detailed version of a timing diagram of the operation of the phase detector 200 during generation of a second down pulse. More specifically, the phase detector 200 compares the positive edge of the reference clock (REF) to the positive edge of the feedback clock (FB). The reference clock signal (REF) is exclusive-ORed (XOR) with the feedback signal (FB) via the exclusive or gate 220. If there is a mismatch between these clocks signals, pulses are generated at Node2. At Node1, the AND gate 230 provides the result of the REF signal being ANDed with the inverse of a delayed version of the REF signal. In certain embodiments, the delay circuit 234 includes a chain of an even number of inverters. Thus, AND gate 230 generates a pulse at every positive edge of the reference clock. The signal at Node1 is then delayed and NANDed with signal provided by the exclusive or gate 220 (node 2). If there is a mismatch between the REF and FB, and if the positive edge of FB is behind the positive edge of REF, a pulse is generated by the NAND gate 238 (Node 3). The width of the pulse generated by the NAND gate 238 depends on the gap between the two positive clock edges of the REF signal and the FB signal. If the gap is small, then the pulse width generated by the NAND gate 238 is narrow.

It is often desirable to provide dynamic circuits with a wider pulse. Accordingly, the narrow pulse is stretched by the stretching circuit 240. After stretching, this signal is sent through a chain of inverters (e.g., inverters 242, delay circuit 282 and inverter 284) to ultimately become a DOWN PULSE.

The down pulse width detector circuit 214 determines the value of a second down pulse by controlling an amount of delay (e.g., via delay 282) that is NANDed with the pulse provided by the stretching circuit 240. The signal provided by inverter 242 (Node 4) is NANDed with the delay provided by delay circuit 282. The amount of delay inserted by delay circuit 282 determines the value of pulse width to be detected and thus when a second down pulse is generated. For example, if the signal at Node4 is delayed by 100 ps, if the pulse at Node4 is greater than 100 ps, a pulse is generated at Node5. The pulse generated by the NAND gate 280 is then stretched and becomes the SECOND DOWN PULSE signal.

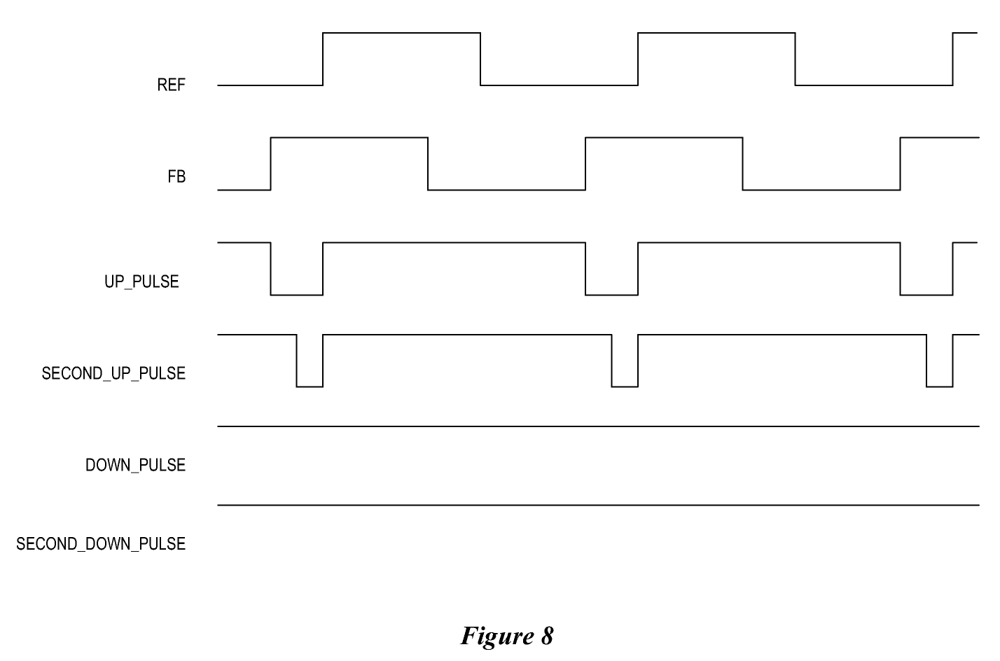

Referring to FIG. 8, a timing diagram of the operation of the phase detector when a positive edge of the feedback signal leads the positive edge of the reference clock signal is shown. Where the positive edge of feedback signal is ahead of the positive edge of the reference signal, an UP PULSE signal and a SECOND UP PULSE signal are created in the same way with DOWN PULSE and SECOND DOWN PULSE.

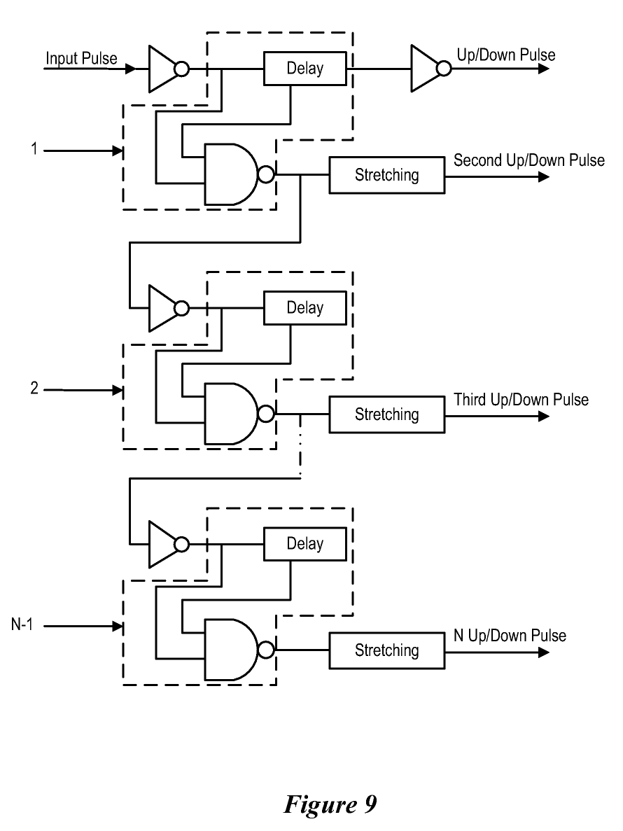

FIG. 9 shows a schematic block diagram of an embodiment of the phase detector in which multiple ranges of differences may be detected. The phase detector 200 can be modified to create additional pulses such as a THIRD PULSE and a FOURTH PULSE when higher gaps between the two clock edges are detected. These additional pulses can be for the up pulses or for the down pulses or for both the up pulses and the down pulses.

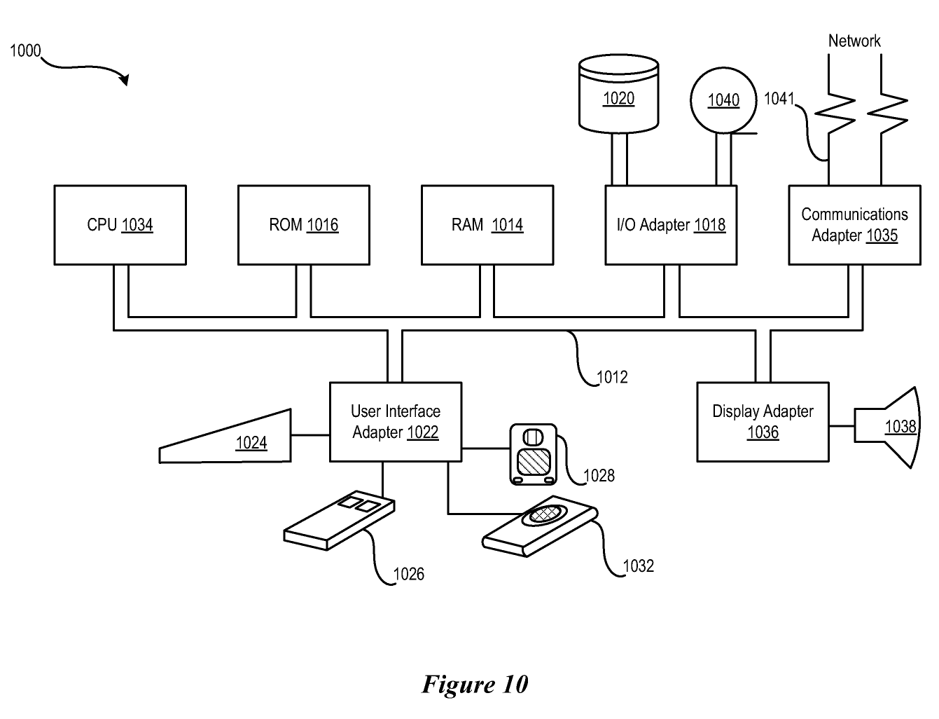

FIG. 10 shows a block diagram of a data processing system suitable for practicing embodiments of the present invention.

FIG. 10 is a high level functional block diagram of a representative data processing system 1000 suitable for practicing the principles of the present invention. Data processing system 1000 includes a central processing system (CPU) 1010 operating in conjunction with a system bus 1012. System bus 1012 operates in accordance with a standard bus protocol, such as the ISA protocol, compatible with CPU 1034. CPU 1034 operates in conjunction with electronically erasable programmable read-only memory (EEPROM) 1016 and random access memory (RAM) 1014. Among other things, EEPROM 1016 supports storage of the Basic Input Output System (BIOS) data and recovery code. RAM 1014 includes DRAM (Dynamic Random Access Memory) system memory and SRAM (Static Random Access Memory) external cache. I/O Adapter 1018 allows for an interconnection between the devices on system bus 1012 and external peripherals, such as mass storage devices (e.g., a hard drive, floppy drive or CD/ROM drive), or a printer 1040. A peripheral device 1020 is, for example, coupled to a peripheral control interface (PCI) bus, and I/O adapter 1018 therefore may be a PCI bus bridge. User interface adapter 1022 couples various user input devices, such as a keyboard 1024 or mouse 1026 to the processing devices on bus 1012. Display 1038 which may be, for example, cathode ray tubes (CRT), liquid crystal display (LCD) or similar conventional display units. Display adapter 1036 may include, among other things, a conventional display controller and frame buffer memory. Data processing system 1000 may be selectively coupled to a computer or telecommunications network 1041 through communications adapter 1034. Communications adapter 1034 may include, for example, a modem for connection to a telecom network and/or hardware and software for connecting to a computer network such as a local area network (LAN) or a wide area network (WAN). CPU 1034 and other components of data processing system 1000 may contain DLL circuitry for local generation of clocks wherein the DLL circuitry employs a phase detector according to embodiments of the present invention to conserve power and to reduce phase jitter. A phase detector in accordance with the present invention may be found within a variety of elements within the data processing system.

Although the present invention and its advantages have been described in detail, it should be understood that various changes, substitutions and alterations can be made herein without departing from the spirit and scope of the invention as defined by the appended claims.

As will be appreciated by one skilled in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product on a computer-usable storage medium having computer-usable program code embodied in the medium.

As will be appreciated by one skilled in the art, while the present invention, and circuits within the present invention are described using certain combinations of logic, other logic combinations are also within the scope of the invention. For example, it will be appreciated other logic combinations to provide a delay circuit and a stretching circuit are known. Also, it will be appreciated that changing the polarity of the logic gates, e.g., from AND to NAND, are also within the scope of the invention.

The block diagrams in the Figures illustrate the architecture, functionality, and operation of possible implementations of systems and methods according to various embodiments of the present invention. It will also be noted that each block of the block diagrams, and combinations of blocks in the block diagrams, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to preferred embodiments thereof, it will be apparent that modifications and variations are possible without departing from the scope of the invention defined in the appended claims.

What is claimed is:

1. A phase frequency detector comprising
a mismatch pulse generator circuit, the mismatch pulse generator circuit receiving a reference clock signal and a feedback clock signal, the mismatch pulse generator circuit generating a mismatch indication pulse when an edge of the reference clock signal is not aligned with an edge of the feedback clock signal, the mismatch indication pulse being proportional to a difference between the edge of the reference clock signal and the edge of the feedback clock signal;
a pulse width detector circuit, the pulse width detector circuit receiving the mismatch indication pulse from the mismatch pulse generator circuit and generating a first pulse, the first pulse indicating that the edge of the reference clock signal and the edge of the feedback clock signal are not aligned, and a second pulse, the second pulse indicating that the edge of the reference clock signal and the edge of the feedback clock signal are not aligned by more than a predetermined amount.

2. The phase frequency detector of claim 1 wherein
the edge of the reference clock signal and the edge of the feedback clock signal are not aligned by either the edge of the reference clock signal leading the edge of the feedback clock signal or the edge of the reference clock signal trailing the edge of the feedback clock signal; and,
the first pulse and the second pulse indicate that the edge of the reference clock signal is leading the edge of the feedback clock signal.

3. The phase frequency detector of claim 2 wherein
the mismatch pulse generator circuit generates a second mismatch indication pulse when the edge of the reference clock signal is trailing the edge of the feedback clock signal; and further comprising
a second pulse width detector, the second pulse width detector circuit receiving the second mismatch indication pulse from the mismatch pulse generator circuit and generating a third pulse, the third pulse indicating that the edge of the reference clock signal is trailing the edge of the feedback clock signal, and a fourth pulse, the fourth pulse indicating that the edge of the reference clock signal is trailing the edge of the feedback clock signal by more than a predetermined amount.

4. The phase frequency detector of claim 1 wherein
the mismatch pulse generator circuit remains stable when the edge of the reference clock signal and the edge of the feedback clock signal are aligned.

5. The phase frequency detector of claim 1 wherein
the pulse width detector circuit further generates a third pulse, the third pulse indicating that the edge of the reference clock signal and the edge of the feedback clock signal are out of synchronization by more than an additional predetermined amount.

6. The phase frequency detector of claim 1 wherein
the edge of the feedback signal is a rising edge and the edge of the reference signal is a rising edge.

7. A phase frequency detector comprising
a mismatch pulse generator circuit, the mismatch pulse generating circuit comprising an edge detection circuit and an exclusive or gate, the exclusive or gate receiving the reference clock signal and the feedback clock signal, the edge detection circuit receiving one of the reference clock signal and the feedback clock signal, the edge detection circuit also receiving an output of the exclusive or gate, the edge detection circuit generating a mismatch indication pulse when an edge of the reference clock signal is not aligned with an edge of the feedback clock signal, the mismatch indication pulse being proportional to a difference between the edge of the reference clock signal and the edge of the feedback clock signal;
a pulse width detector circuit, the pulse width detector circuit receiving the mismatch indication pulse from the mismatch pulse generator circuit and generating a first pulse, the first pulse indicating that the edge of the reference clock signal and the edge of the feedback clock signal are out of synchronization, and a second pulse, the second pulse indicating that the edge of the reference clock signal and the edge of the feedback clock signal are out of synchronization by more than a predetermined amount.

8. The phase frequency detector of claim 7 wherein
the edge of the reference clock signal and the edge of the feedback clock signal are not aligned by either the edge of the reference clock signal leading the edge of the feedback clock signal or the edge of the reference clock signal trailing the edge of the feedback clock signal; and,
the first pulse and the second pulse indicate that the edge of the reference clock signal is leading the edge of the feedback clock signal.

9. The phase frequency detector of claim 8 wherein
the mismatch pulse generator circuit further comprises a second edge detection circuit, the second edge detection circuit receiving another of the reference clock signal and the feedback clock signal, the second edge detection circuit also receiving an output of the exclusive or gate, the second edge detection circuit generating a second mismatch indication pulse when an edge of the reference clock signal is not aligned with an edge of the feedback clock signal, the second mismatch indication pulse being proportional to a difference between the edge of the reference clock signal and the edge of the feedback clock signal;
the second mismatch indication pulse being generated when the edge of the reference clock signal is trailing the edge of the feedback clock signal; and further comprising
a second pulse width detector, the second pulse width detector circuit receiving the second mismatch indication pulse from the mismatch pulse generator circuit and generating a third pulse, the third pulse indicating that the edge of the reference clock signal is trailing the edge of the feedback clock signal, and a fourth pulse, the fourth pulse indicating that the edge of the reference clock signal is trailing the edge of the feedback clock signal by more than a predetermined amount.

10. The phase frequency detector of claim 7 wherein
the mismatch pulse generator circuit remains stable when the edge of the reference clock signal and the edge of the feedback clock signal are aligned.

11. The phase frequency detector of claim 7 wherein
the pulse width detector circuit further generates a third pulse, the third pulse indicating that the edge of the reference clock signal and the edge of the feedback clock signal are out of synchronization by more than an additional predetermined amount.

12. The phase frequency detector of claim 7 wherein
the edge of the feedback signal is a rising edge and the edge of the reference signal is a rising edge.

13. A method of detecting a phase frequency comprising
comparing a reference clock signal with a feedback clock signal;
generating a mismatch indication pulse when an edge of the reference clock signal is not aligned with an edge of the feedback clock signal, the mismatch indication pulse being proportional to a difference between the edge of the reference clock signal and the edge of the feedback clock signal;
generating a first pulse, the first pulse indicating that the edge of the reference clock signal and the edge of the feedback clock signal are out of synchronization; and,
generating a second pulse, the second pulse indicating that the edge of the reference clock signal and the edge of the feedback clock signal are out of synchronization by more than a predetermined amount.

14. The method of claim 13 wherein
the edge of the reference clock signal and the edge of the feedback clock signal are not aligned by either the edge of the reference clock signal leading the edge of the feedback clock signal or the edge of the reference clock signal trailing the edge of the feedback clock signal; and,
the first pulse and the second pulse indicate that the edge of the reference clock signal is leading the edge of the feedback clock signal.

15. The method of claim 14 further comprising
generating a second mismatch indication pulse when the edge of the reference clock signal is trailing the edge of the feedback clock signal;
generating a third pulse, the third pulse indicating that the edge of the reference clock signal is trailing the edge of the feedback clock signal; and,
generating a fourth pulse, the fourth pulse indicating that the edge of the reference clock signal is trailing the edge of the feedback clock signal by more than a predetermined amount.

16. The method of claim 13 further comprising
generating a stable signal when the edge of the reference clock signal and the edge of the feedback clock signal are aligned.

17. The method of claim 13 further comprising
generating a third pulse, the third pulse indicating that the edge of the reference clock signal and the edge of the feedback clock signal are out of synchronization by more than an additional predetermined amount.

18. The method of claim 13 wherein
the edge of the feedback signal is a rising edge and the edge of the reference signal is a rising edge.
